(19) United States
(12) Patent Application Publication
(10) Pub. No.: US 2025/0075325 A1
(43) Pub. Date: Mar. 6, 2025

(54) SUBSTRATE PROCESSING SYSTEM WITH A CAPABILITY TO MONITOR GATE VALVES AND THE METHOD THEREOF

(71) Applicant: ASM IP Holding B.V., Almere (NL)

(72) Inventor: Hoon Cho, Hwaseong-si (KR)

(21) Appl. No.: 18/815,322

(22) Filed: Aug. 26, 2024

Related U.S. Application Data
(60) Provisional application No. 63/535,452, filed on Aug. 30, 2023.

(51) Int. Cl. C23C 16/52; C23C 16/455

(52) U.S. Cl. CPC C23C 16/52; C23C 16/45561

(57) ABSTRACT

Semiconductor processing system with a capability to monitor gate valves and the method thereof is presented. In the present disclosure, a semiconductor processing system, comprising a reaction chamber, a gate valve coupled to the reaction chamber and a controller operably connected to the gate valve and configured to open and close the gate valve, wherein the controller further configured to calculate an average operation time of the gate valve, set parameters, measure an operation time of the gate valve, and determine the gate valve to be abnormal if the operation time of the gate valve is not within normal range based on the parameters. With the present disclosure, the gate valves can be monitored in real time, which may enable a better substrate processing and better wafer quality.

### CROSS-REFERENCE TO RELATED APPLICATION(S)

This Application claims the benefit of U.S. Provisional Application 63/535,452 filed on Aug. 30, 2023, the entire contents of which are incorporated herein by reference.

### FIELD OF INVENTION

The present disclosure relates to a semiconductor processing system, particularly to a system equipped with a capability to monitor the gate valves coupled to reaction chambers in the system.

### BACKGROUND OF THE DISCLOSURE

Semiconductor devices are commonly formed by depositing films onto substrates with deposition techniques such as atomic layer deposition (ALD) or chemical vapor deposition (CVD). ALD and/or CVD techniques generally employ providing flows of precursors or reactant gases to a reaction chamber cyclically for relatively short periods of time to form a desired layer on an individual substrate.

The gas flows may be typically provided by gate valves, which open and close according to a predetermined, scheduled time and it could be done by a gate valve controller. The quality of the deposited film may depend on the extent the precise gate valve open and close.

However, the gate valves may get rusty or old so that they would not respond to the open/close signals as exactly as expected so that unstable gas pressure and/or gate valve operation timeout would occur during substrate processing.

Therefore, the present disclosure presents a system and a method to monitor the gate valves' responsiveness to open/close signals so that it would be easy to maintain the product quality.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In accordance with one embodiment there may be provided, a method of monitoring a gate valve in a semiconductor processing system, the method comprising: calculating an average operation time of the gate valve; setting parameters; measuring an operation time of the gate valve; and determining the gate valve to be abnormal if the operation time of the gate valve is not within normal range based on the parameters.

In accordance with another embodiment there may be provided, displaying the gate valve's status.

In accordance with another embodiment there may be provided, the method further comprising displaying the gate valve's status.

In accordance with another embodiment there may be provided, the method further comprising receiving parameters from a user interface; and saving the received parameters.

In accordance with another embodiment there may be provided, the calculating further comprising: sending a valve on signal to a gate valve; receiving a feedback signal from the gate valve; and counting a time elapsed between the valve on signal and the feedback signal and repeating the sending, the receiving and the counting a predetermined number of times to determine an average operation time of the gate valve.

In accordance with another embodiment there may be provided, the measuring further comprising: sending a valve on signal to the gate valve; receiving a feedback signal from the gate valve; counting a time elapsed between the valve on signal and the feedback signal and determine the elapsed time to be an operation time of the gate valve.

In accordance with another embodiment there may be provided, a semiconductor processing system, comprising: a reaction chamber; a gate valve coupled to the reaction chamber; and a controller operably connected to the gate valve and configured to open and close the gate valve; wherein the controller further configured to: calculate an average operation time of the gate valve; set parameters; measure an operation time of the gate valve; and determine the gate valve to be abnormal if the operation time of the gate valve is not within normal range based on the parameters.

In accordance with another embodiment there may be provided, the system further comprising: an input unit configured to get inputs from an operator; and a display unit configured to display the status of the gate valve, wherein the input unit and the display unit are coupled to the controller with wire or wirelessly and the controller further configured to display the gate valve's status to the display unit.

In at least one aspect, the input unit configured to receive inputs in text form or in graphical form and further configured to save the inputs to a memory.

In accordance with another embodiment there may be provided, the controller further configured to send a valve on signal to the gate valve; receive a feedback signal from the gate valve; and count the time elapsed between the valve on signal and the feedback signal and repeat them with predetermined number of times to get an average operation time of the gate valve.

In accordance with another embodiment there may be provided, the controller further configured to send a valve on signal to the gate valve; receive a feedback signal from the gate valve; and counting a time elapsed between the valve on signal and the feedback signal and determine the elapsed time to be an operation time of the gate valve.

In accordance with another embodiment there may be provided, a non-transitory, computer-readable and tangible medium having stored thereon a set of instructions that are executable by a processor of a computer system to carry out the methods above.

### BRIEF DESCRIPTION OF THE DRAWING FIGURES

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

FIG. 1 illustrates a substrate processing system according to an embodiment of the present disclosure.

FIG. 2(a) illustrates an overall flowchart of the gate valve monitoring method according to another embodiment of the present disclosure.

FIG. 2(b) illustrates a flowchart of getting average operation time of a gate valve according to another embodiment of the present disclosure.

FIG. 2(c) illustrates a flowchart of getting an operation time of a gate valve according to another embodiment of the present disclosure.

FIG. 3 illustrates the user interface portion of the system according to an embodiment of the present disclosure.

FIG. 4(a) illustrates an example of a ‘text-based’ user interface for selecting which gate valve would be tested according to an embodiment of the present disclosure.

FIG. 4(b) illustrates an example of a ‘graphic-based’ user interface for selecting which gate valve would be tested according to another embodiment of the present disclosure.

FIG. 5(a) illustrates an example of a case in which the gate valve may be tested normal according to an embodiment of the present disclosure.

FIG. 5(b) illustrates an example of a case in which the gate valve may be tested abnormal due to ‘too fast’ according to an embodiment of the present disclosure.

FIG. 5(c) illustrates an example of a case in which the gate valve may be tested abnormal due to ‘too slow’ according to an embodiment of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include substrates in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

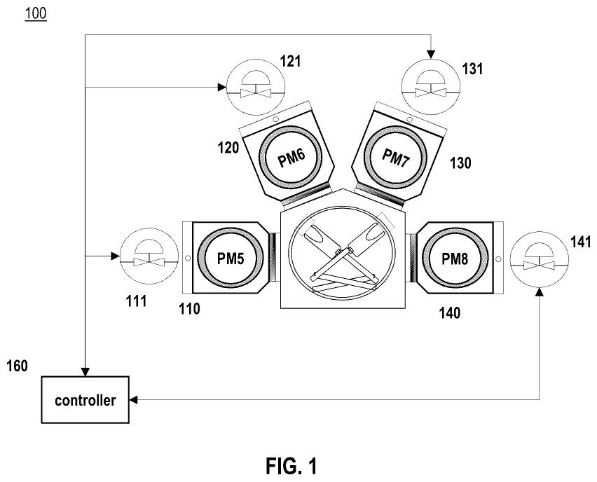

FIG. 1 illustrates the overall substrate processing system 100 according to an embodiment presented in the present disclosure.

The system comprises reaction chambers 110, 120, 130, 140, gate valves 111, 121, 131, 141 coupled to the reaction chambers 110, 120, 130, 140 respectively and a controller 160.

In this specification, for simplicity, a gate valve sensor may be thought to be incorporated with its gate valve. Therefore, signals could be sent and received by a gate valve.

The controller 160 may be operably connected to the gate valves 111, 121, 131, 141 and further configured to send valve on signals to control the gate valves 111, 121, 131, 141. The controller 160 may also be configured to receive the feedback signals from the gate valves 111, 121, 131, 141 confirming that the gate valves 110, 120, 130, 140 are operated by the signals (valve on signal for example) it sent earlier.

The controller 160 may further be configured to measure the time when signals are sent or received.

Also, the controller 160 may further be configured to calculate an average operation time and operation time of a gate valve. ‘Operation time’ means the time between a time when ‘valve on signal’ (to open a gate valve) may be sent and a time when ‘feedback signal’ (confirming that the gate valve is operated as instructed) may be received by the controller 160. ‘Average operation time’ would mean the average time of the operation time measured in multiple times, usually predetermined number of times.

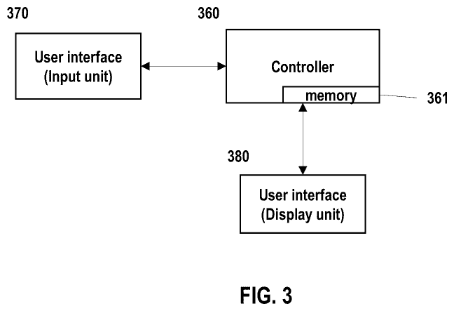

FIG. 3 illustrates the controller and user interface according to an embodiment of the present disclosure.

The controller 360 may be operably connected with user interface 370, 380.

Input user interface 370 and output user interface (Display unit) 380 could be separate as shown in FIG. 3. The controller 360 may comprise a memory unit 361 for saving the parameters such as average operation times for all the gate valves in the system.

In all, the controller 160, 360 may configured to 1) calculate an average operation time of the gate valve, 2) set parameters, 3) measure an operation time of the gate valve and 4) determine the gate valve to be abnormal if the operation time of the gate valve is not within normal range based on the parameters.

The parameters may be predetermined and saved inside the controller 360 but they could be input into the controller 360 through the input user interface 370.

The parameters would be 1) valid range with an average operation time in the middle and 2) valve timeout for each gate valve.

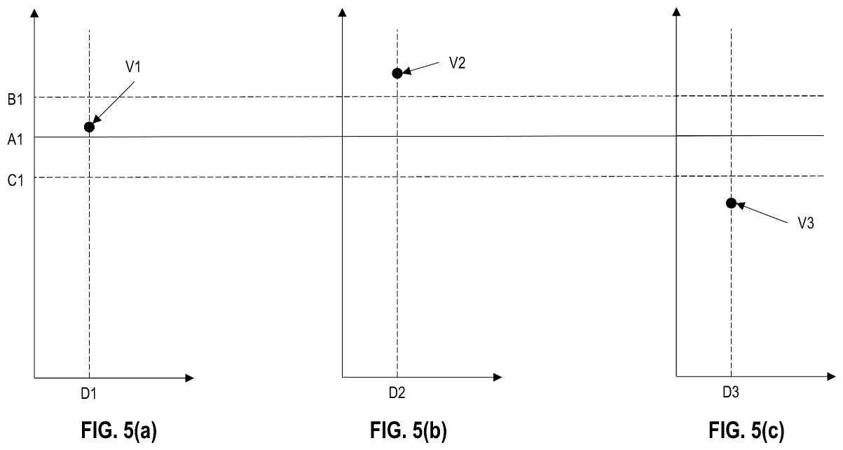

FIGS. 5(a)-5(c) illustrate the 3 different cases of when a gate valve is determined to be normal in function or not.

FIGS. 5(a)-5(c) share the same ‘average operation time’ (A1), the upper bound of the valid range (B1), the lower bound of the valid range (C1), and the valve timeout (D1).

FIG. 5(a) illustrates a case when the operation time of a gate valve is somewhere (V1) between the lower bound and the upper bound of the valid range when the valve timeout expires (D1).

When the controller 160, 360 measures the operation time of a gate valve like this case, then the controller 160, 360 would determine the gate valve to be normal in function.

However, as shown in FIGS. 5(b) and 5(c), if the operation time of a gate valve measures above the upper bound (V2) or below the lower bound (V3) and in both cases the controller 160, 360 may determine the gate valve to be abnormal in function.

A gate valve responds to signals too slow (V3) would be a good reason to be determined to be abnormal, but a gate valve responds to signals too fast (V2) would too be determined to be abnormal since the valve operation's synchronization is one of the important factors in the substrate processing with reactant gases or precursors.

The valve open operation may be used to determine whether a gate valve is normal or abnormal, but valve close operation may also be used to determine whether a gate valve is normal or not.

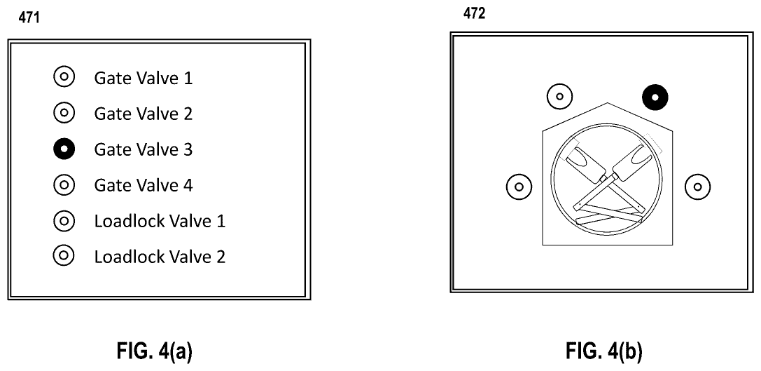

FIGS. 4(a) and 4(b) show two different types of input form the input user interface 370. FIG. 4(a) may be a text-based form and FIG. 4(b) may be a graphic-based form to select what gate valve to monitor.

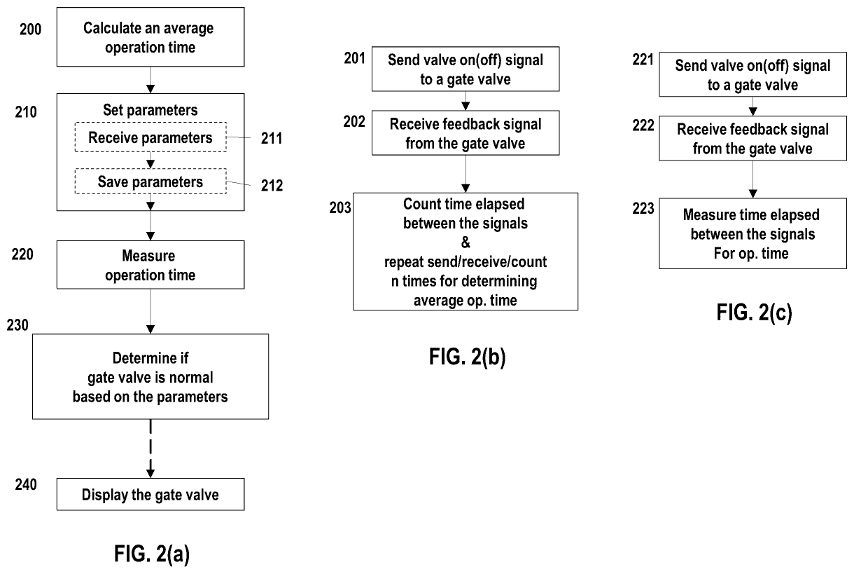

FIG. 2(a) illustrates the flowchart of a method of monitoring the gate valves according to an embodiment of the present disclosure.

At first, a gate valve's average operation time is calculated (200).

As shown in FIG. 2(b), the calculating may comprise sending valve on signal to a gate valve (201), after that receiving a feedback signal from the gate valve (202). After receiving, counting the time elapsed between the time of sending and the time of receiving and repeat this sending, receiving and counting a predetermined number of times (preferably 10 times) to determine an average operation time of the gate valve (203).

After calculating the average operation time of a gate valve (200), parameters are to be set (210). The parameter setting may comprise receiving parameters from user interface (211) and saving the parameters into a memory (212).

Then measuring operation time may take place (220). As shown in FIG. 2(c) shows measuring may comprise sending a valve on signal to the gate valve (221), receiving a feedback signal from the gate valve (222), and counting a time elapsed between the valve on signal and the feedback signal and determine the elapsed time to be an operation time of the gate valve (223).

After measuring the operation time, based on the parameters (such as valid range & valve timeout) whether the gate valve is normal in function may be determined (230). This determining would be done with the use of the graph shown in FIGS. 5(a)-5(c).

After a gate valve is determined to be normal or abnormal, the result would be displayed (240) and this displaying would be taking place on the display unit 380.

Valve on signal (gate valve open signal) as well as valve off signal (gate valve close signal) may be used in the calculating and the measuring.

The above-described arrangements of system are merely illustrative of applications of the principles of this invention and many other embodiments and modifications may be made without departing from the spirit and scope of the invention as defined in the claims. The scope of the invention should, therefore, be determined not with reference to the above description, but instead should be determined with reference to the appended claims along with their full scope of equivalents.

1. A method of monitoring a gate valve in a semiconductor processing system, the method comprising:
calculating an average operation time of the gate valve;
setting parameters;
measuring an operation time of the gate valve; and
determining the gate valve to be abnormal if the operation time of the gate valve is not within normal range based on the parameters.

2. The method according to claim 1, further comprising:
displaying status of the gate valve.

3. The method according to claim 1, wherein the setting further comprises:
receiving parameters from a user interface; and
saving the received parameters.

4. The method according to claim 1, wherein the calculating further comprises:
sending a valve on signal to a gate valve;
receiving a feedback signal from the gate valve;
counting a time elapsed between the valve on signal and the feedback signal; and
repeating the sending, the receiving and the counting a predetermined number of times to determine an average operation time of the gate valve.

5. The method according to claim 1, wherein the measuring further comprises:
sending a valve on signal to the gate valve;
receiving a feedback signal from the gate valve;
counting a time elapsed between the valve on signal and the feedback signal; and
determine the elapsed time to be an operation time of the gate valve.

6. A semiconductor processing system, comprising:
a reaction chamber;
a gate valve coupled to the reaction chamber; and
a controller operably connected to the gate valve and configured to open and close the gate valve; wherein the controller further configured to:
calculate an average operation time of the gate valve;
set parameters;
measure an operation time of the gate valve; and
determine the gate valve to be abnormal if the operation time of the gate valve is not within normal range based on the parameters.

7. A substrate processing system according to claim 6, further comprising:
an input unit configured to get inputs from an operator; and
a display unit configured to display the status of the gate valve,
wherein the input unit and the display unit are coupled to the controller with wire or wirelessly and
the controller further configured to display the status of the gate valve to the display unit.

8. A substrate processing system according to claim 7, wherein
the input unit is configured to receive inputs in text form or in graphical form and further configured to save the inputs to a memory.

9. A substrate processing system according to claim 6, wherein the controller is further configured to perform steps of:
sending a valve on signal to the gate valve;
receiving a feedback signal from the gate valve;
counting time elapsed time between the valve on signal and the feedback signal; and
repeating the sending, the receiving and the counting a predetermined number of times to get an average operation time of the gate valve.

10. A substrate processing system according to claim 6, wherein the controller is further configured to:
send a valve on signal to the gate valve;
receive a feedback signal from the gate valve;
count a time elapsed between the valve on signal and the feedback signal; and
determine the elapsed time to be an operation time of the gate valve.

11. A non-transitory, computer-readable and tangible medium having stored thereon a set of instructions that are executable by a processor of a computer system to carry out the method of claim 1.
